(19) United States
(12) Patent Application Publication
(10) Pub. No.: US 2026/0113997 A1
(43) Pub. Date: Apr. 23, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Shao-Ming YU, Hsinchu County (TW); Wei-Sheng YUN, Taipei City (TW); YunYan CHUNG, Hsinchu City (TW); Tung Ying LEE, Hsinchu City (TW); Chao-Ching CHENG, Hsinchu City (TW)

(73) Assignee: TAIWAN SEMICONDUCTOR MANUFACTURING COMPANY, LTD., Hsinchu (TW)

(21) Appl. No.: 18/923,039

(22) Filed: Oct. 22, 2024

(51) Int. Cl. H01L 29/06; H01L 27/092; H01L 29/423; H01L 29/51; H01L 29/66; H01L 29/775; H01L 29/786

(52) U.S. Cl. CPC H10D 62/116; H10D 30/0217; H10D 64/685; H10D 64/691; H10D 30/014; H10D 30/43; H10D 30/6735; H10D 30/6757; H10D 62/121; H10D 84/856

(57) ABSTRACT

A method includes forming an etch stop layer over a substrate; forming a stack of alternating channel layers and sacrificial layers over the etch stop layer; etching the stack, until the etch stop layer is exposed, to form a fin-shaped structure; forming a source/drain features opposite sides of the stack; removing the sacrificial layers to release the channel layers; forming a gate structure to wrap around each of the channel layers.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2A-16B illustrate the cross-sectional views of intermediate stages in the formation of a semiconductor structure in accordance with some embodiments.

FIGS. 17A-19C illustrate the cross-sectional views of intermediate stages in the formation of a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

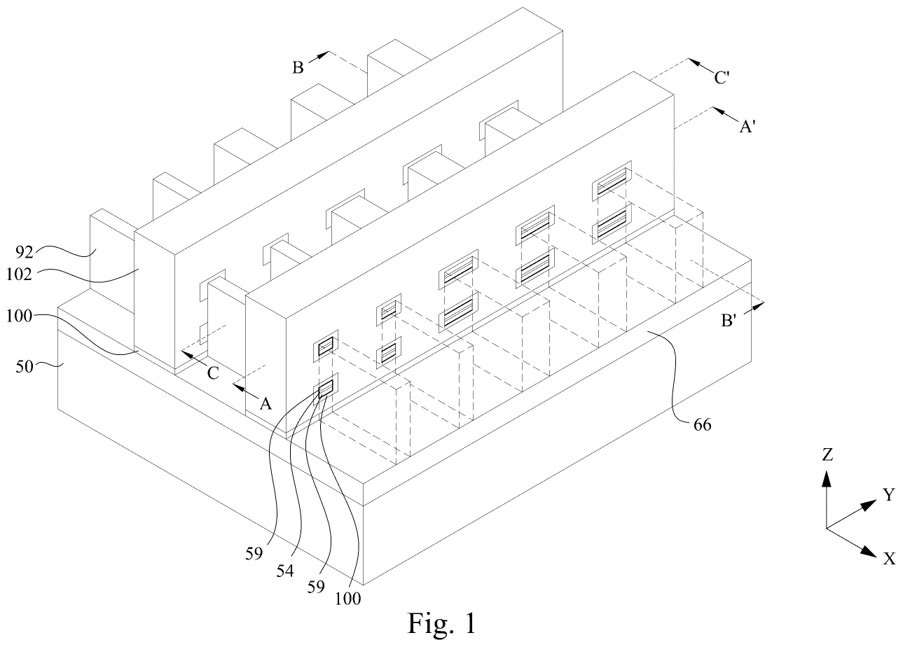

Reference is made to FIG. 1. FIG. 1 illustrates an example of nano-FETs (e.g., nanowire FETs, nanosheet FETs (Nano-FETs), or the like) in a three-dimensional view, in accordance with some embodiments. Certain features can be simplified and/or omitted in FIG. 1 for ease of illustration. The nano-FETs comprise nanostructures 54 (e.g., nanosheets, nanowire, or the like) over a substrate 50 (e.g., a semiconductor substrate), wherein the nanostructures 54 act as channel regions for the nano-FETs. In some embodiments, two-dimensional (2D) materials can be implemented to form the alternative structures for the semiconductor-based channel regions. The 2D materials can be mono-layers of materials held together by chemical bonds and have outstanding electrical and physical properties. Mono-layers can be stacked on each other to form a 2D material layer that includes individual monolayers. In some embodiments, individual monolayers of graphene, thin layers of black phosphorus (also known as phosphorene), graphene analogues (such as silicene, gemanene, stannene, etc.), and/or boron nitride can be stacked to create the 2D material layer. Another example of a 2D material can be transition metal dichalcogenides (TMDs). The TMDs can have a general formula of MX₂, where M denotes a transition metal from, for example, periodic table column {IVB, VB, VIB} (e.g., molybdenum (Mo), tungsten (W), niobium (Nb), haftnium (Hf), or tantalum (Ta)), and X denotes an element from the group of {sulfur (S), selenium (Se), or tellurium (Te)}.

In some embodiments, the electrical properties of the 2D (two-dimension) materials can make them candidates for use in transistors structures. In some embodiments, a S/D doping process can be omitted, since the surfaces of the 2D materials can demonstrate metallic/conductive behavior when they are in contact with metal, and conductive channel regions made by 2D materials can be quickly and reliably turned on or off by applying suitable gate voltages. Additionally, the semiconductor device in accordance with some embodiments can provide a high packing density. The compact vertical structures and minimal body thickness made possible by thin layered 2D materials can allow further reduction in device dimension without sacrificing device performance, and in turn results in high packing density. Therefore, the implementation of suitable 2D materials in 3D device architectures can yield further scaled, high-performance low-power devices adaptable for aggressive gate lengths.

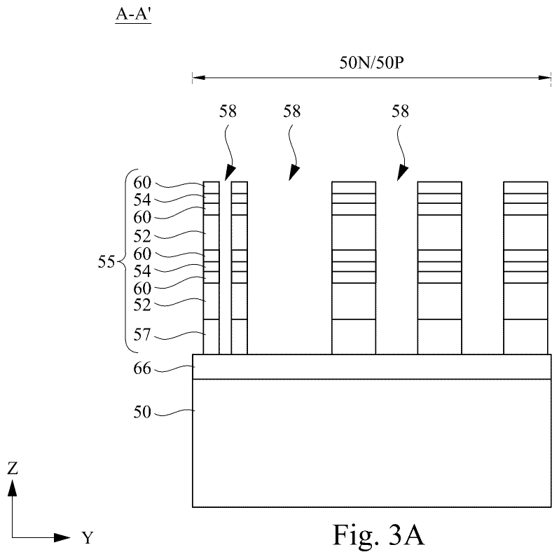

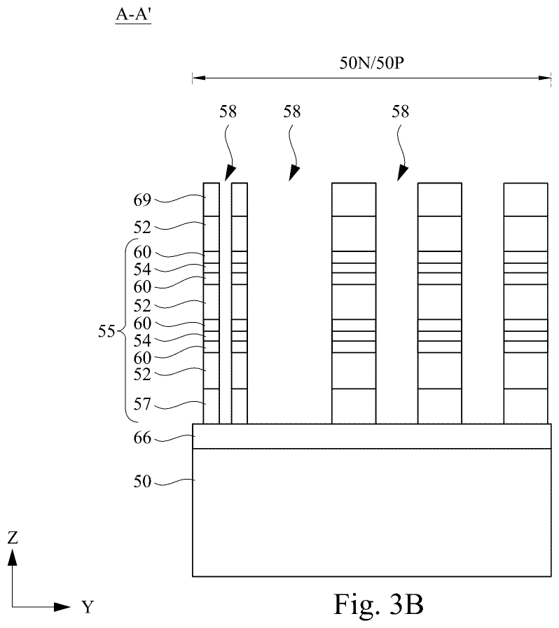

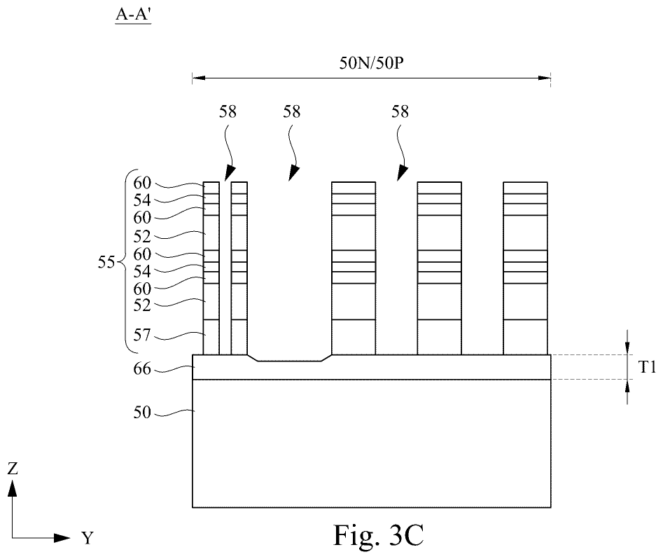

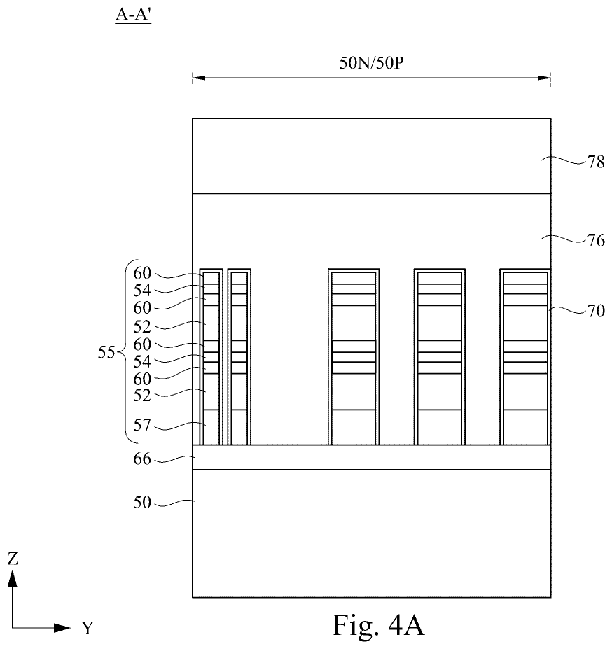

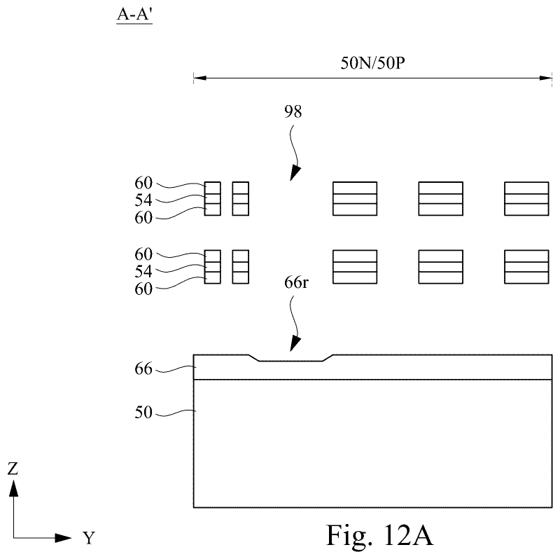

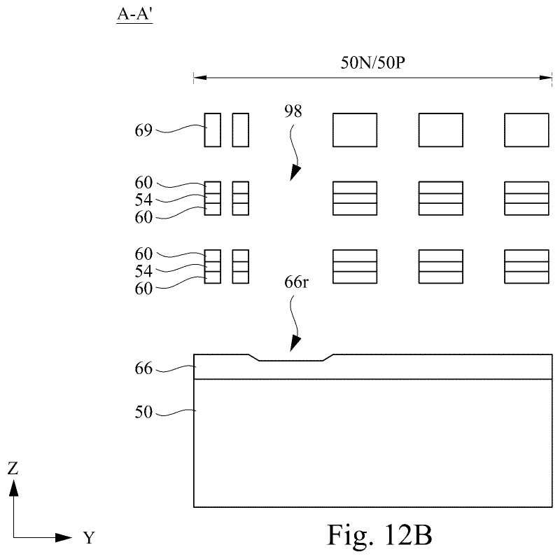

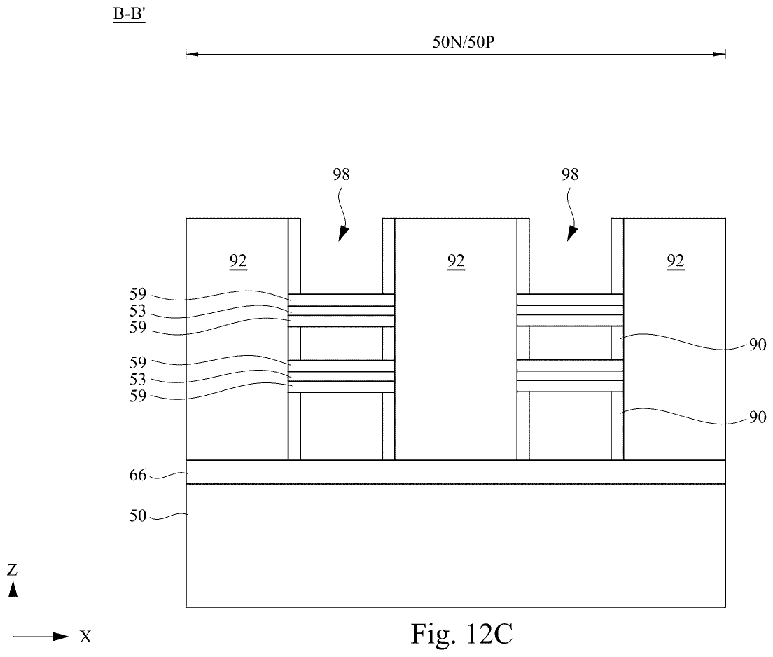

An etch stop layer 66 can be disposed over the substrate 50 and underlies the nanostructures 54. Although the etch stop layer 66 can be described/illustrated as being separate from the substrate 50, as used herein, the term “substrate” may refer to the semiconductor substrate alone or a combination of the semiconductor substrate and the isolation regions. In some embodiments, etching processes for forming stacked nanostructures 54 (e.g., 2D material nanosheets) in the creation of fin patterns (e.g., active region/OD (i.e. oxide definition) etch as shown in FIGS. 3A-3C) and the formation of the nanostructures 54 (e.g., nanosheet release etch as shown in FIG. 12A-12C) may face some challenges. For example, small and large pattern sizes (i.e., patterning loading effect) may result in variations in step height in the substrate underlying the nanostructures 54 during the OD etch, leading to non-uniformity. Additionally, during the nanosheet release etch, there is insufficient selectivity between the dielectric layers (e.g., SiO₂ or SiN) and the substrate 50, which can lead to substrate damage and pattern collapse.

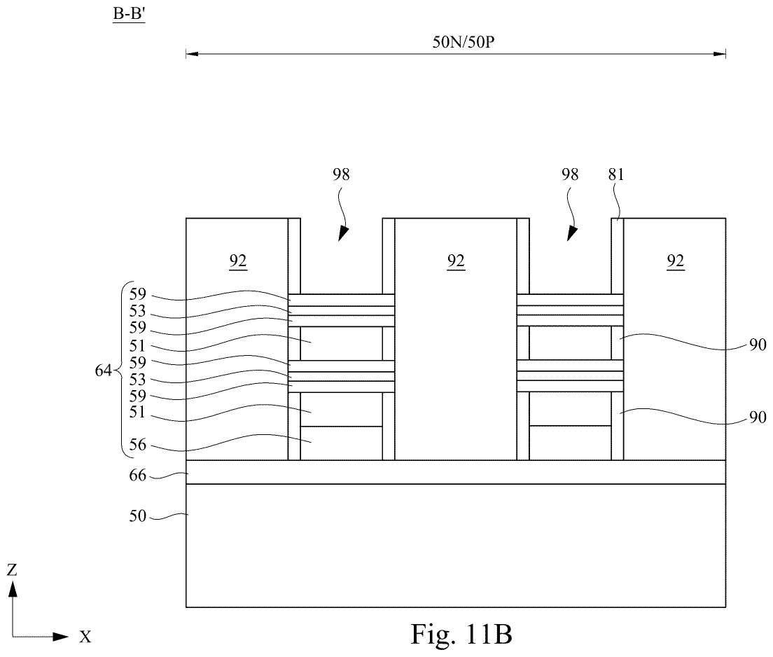

Therefore, the present disclosure in various embodiments provides an incorporation of a high-k dielectric material (e.g., hafnium oxide (HfO₂)) etch stop layer in both the OD etch (see FIGS. 3A-3C) and sheet release etch processes (see FIGS. 12A-12C) to address these challenges. For example, a high etching selectivity between the high-k dielectric material etch stop layer 66 and other materials (e.g., SiN/SiO₂) can achieve over 10 of an etching selectivity ratio. Integration of high-k dielectric material below the nanostructure 56 (e.g., SiO₂ layer) to act as an etch stop can improve process window and reduce pattern loading effects, which in turn improves pattern fidelity and uniformity. In the sheet release step, a gas mixture including, such as carbon tetrafluoride (CF₄) gas, can be used to etch out the nanostructures 52, 56 (see FIGS. 11A-12C) while preserving the nanostructures 54 and the etch stop layer 66. Placement of the etch stop layer 66 above the substrate 50 to act as an etch stop during etching, enhancing selectivity and protecting the substrate, which in turn prevents excessive etching of the substrate 50.

Gate dielectric layers 100 are over top surfaces of the etch stop layer 66 and along top surfaces, sidewalls, and bottom surfaces of the nanostructures 54. Gate electrodes 102 can be over the gate dielectric layers 100. Source/drain regions 92 can be disposed on opposing sides of the nanostructures 54. Source/drain region(s) 92 may refer to a source or a drain, individually or collectively dependent upon the context. In some embodiments, the source/drain region 92 can be interchangeable referred to as a source/drain pattern, a source/drain layer, a source/drain structure, a source/drain node, or a source/drain terminal.

FIG. 1 further illustrates reference cross-sections that are used in later figures. Cross-section A-A′ is along a longitudinal axis of a gate electrode 102 and in a direction, for example, perpendicular to the direction of current flow between the source/drain regions 92 of a nano-FET. Cross-section B-B′ is perpendicular to cross-section A-A′ and is parallel to a direction of, for example, a current flow between the source/drain regions 92 of the nano-FET. Cross-section C-C′ is parallel to cross-section A-A′ and extends through source/drain regions of the nano-FETs. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

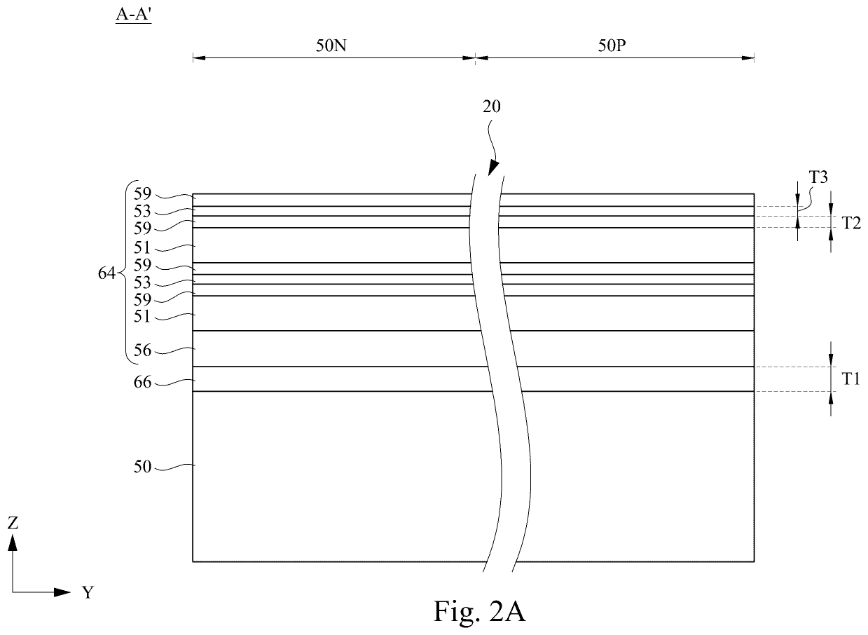

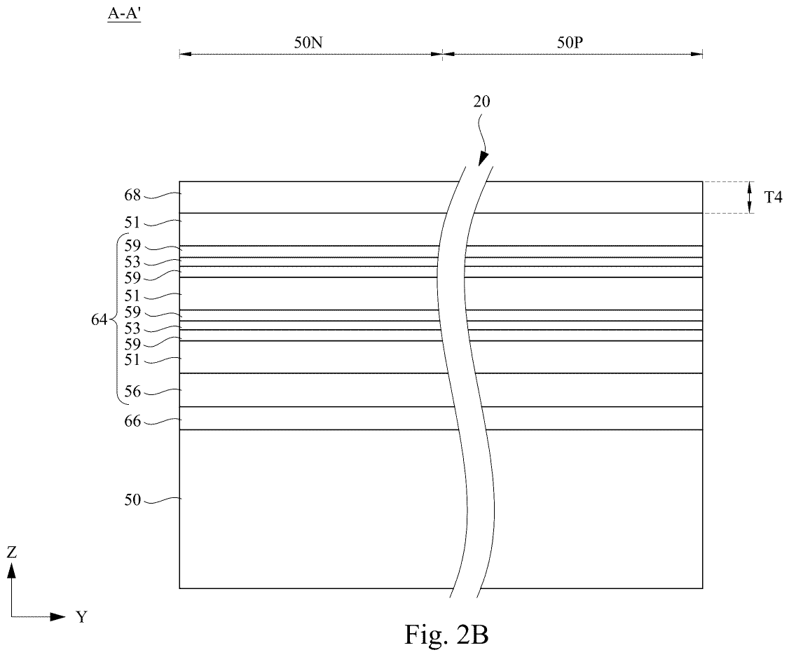

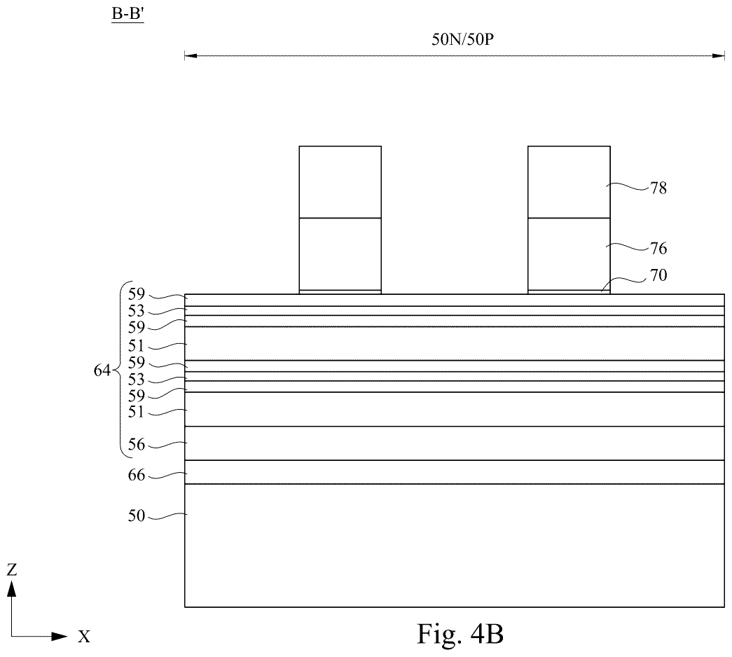

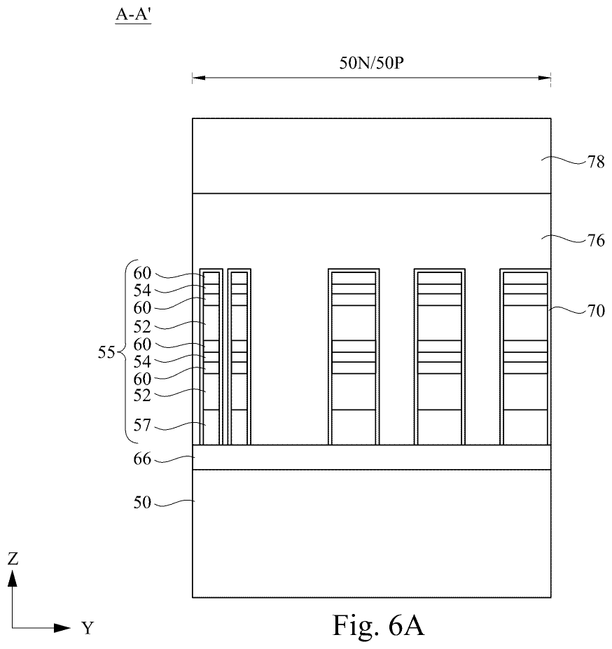

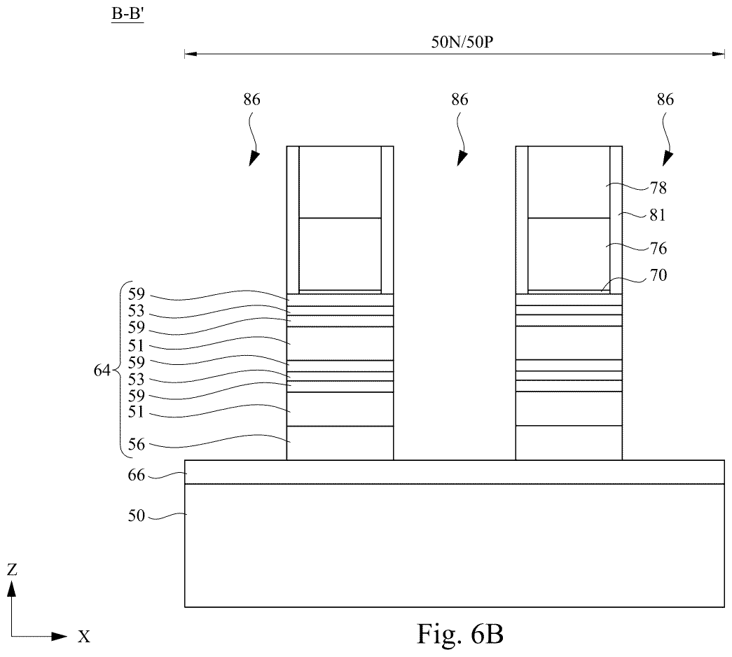

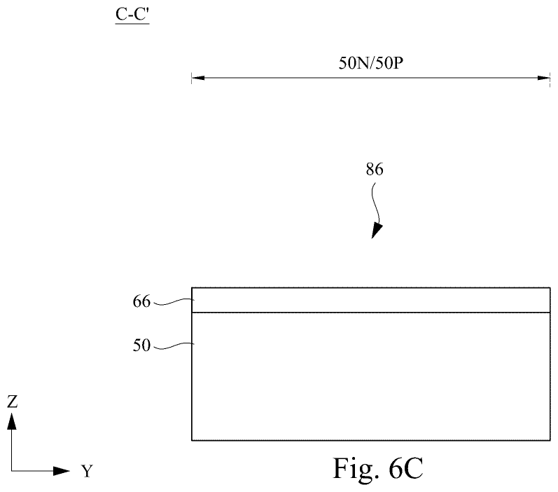

Reference is made to FIGS. 2A-16B. FIGS. 2A-16B illustrate the cross-sectional views of intermediate stages in the formation of a semiconductor structure in accordance with some embodiments. FIGS. 2A-3C, 4A, 5A, 6A, 7A, 8A, 9A, 10A, 11A, 12A, 12B, 13A, 14A, 15A, and 16A illustrate reference cross-section A-A′ illustrated in FIG. 1. FIGS. 4B, 5B, 6B, 7B, 8B, 9B, 10B, 11B, 12C, 13B, 14B, 15B, and 16B illustrate reference cross-section B-B′ illustrated in FIG. 1. FIG. 6C illustrates reference cross-section C-C′ illustrated in FIG. 1.

Reference is made to FIG. 2A. A substrate 50 can be provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 can have an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2A, an etch stop layer 66 can be disposed over the substrate 50. In some embodiments, the etch stop layer 66 can act as an etch stop during the OD etch (see FIGS. 3A-3C). In some embodiments, the etch stop layer 66 can act as an etch stop during etching, enhancing selectivity and protecting the substrate, which in turn prevents excessive etching of the substrate 50. In some embodiments, the deposition of the etch stop layer 66 can be performed using a conformal deposition process such as physical vapor deposition (PVD), CVD, ALD, or the like. In some embodiments, the etch stop layer 66 may be formed of metal oxide. In some embodiments, the etch stop layer 66 may be formed of a material having a dielectric constant greater than about 9 (e.g., high dielectric constant (high-k) material). For example, the etch stop layer 66 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The etch stop layer 66 may be formed of a homogenous material, or may have a composite structure including more than one layer.

Further in FIG. 2A, a multi-layer stack 64 can formed over the substrate 50. The multi-layer stack 64 can include a dielectric layer 56 and alternating layers of dielectric layers 51 and 2D material layers 53 over the dielectric layer 56. For purposes of illustration and as discussed in greater detail below, the dielectric layers 51 will be removed and the 2D material layers 53 will be patterned to form channel regions of nano-FETs in both the n-type region 50N and the p-type region 50P. In some embodiments, the channel regions of the n-type region 50N may have a different material composition than the channel regions of the p-type region 50P. The multi-layer stack 64 is illustrated as including two layers of each of the dielectric layers 51 and the 2D material layers 53 for illustrative purposes. In some embodiments, the multi-layer stack 64 may include any number of the dielectric layers 51 and the 2D material layers 53.

Further in FIG. 2A, the multi-layer stack 64 can further include protective layers 59 formed over a top surface and a bottom surface of the 2D material layer 53. In some embodiments, a thickness T1 of the etch stop layer 66 is more than twice a thickness T2 of the protective layer 59. By way of example and not limitation, the thickness T1 of the etch stop layer 66 can be in a range from about 5-20 nm, such as about 5, 6, 8, 10, 12, 14, 16, 18, or 20 nm. In some embodiments, the thickness of the protective layer 59 can be in a range from about 1-10 nm, such as about 1, 2, 3, 4, 5, 6, 7, 8, 9, or 10 nm. In some embodiments, a thickness T3 of 2D material layers 53 can be less than the thickness T2 of the protective layer 59. By way of example and not limitation, the thickness T3 of the 2D material layers 53 can be less than about 2 nm, such as about 2, 4, 6, 8, 10, 112, 14, 16, 18, or 20 angstrom.

In some embodiments, the dielectric layer 51/56 may be formed of a dielectric material, such as a nitride-based material, such as Si₃N₄, SiON, or a carbon-based material, such as SiC, SiOC, SiOCN, or combinations thereof. In some embodiments, the hard mask layer 235 may include SiOₓ, SiBN, SiCBN, other suitable dielectric materials, or combinations thereof. In some embodiments, the dielectric layer 51 can be made of a different material than the dielectric layer 56. For example, the dielectric layer 51 may be made of silicon nitride while the dielectric layer 56 may be made of silicon oxide. In some embodiments, the dielectric layer 51 can be made of a same material as the dielectric layer 56. In some embodiments, the dielectric layer 51/56 can be formed using suitable deposition methods, including but not limited to chemical vapor deposition (CVD), plasma-enhanced chemical vapor deposition (PECVD), atomic layer deposition (ALD), plasma-enhanced atomic layer deposition (PEALD), or the like.

In some embodiments, the 2D material layers 53 may be formed of a 2D material. In some embodiments, the 2D material layer 53 can be mono-layers of materials held together by chemical bonds and have outstanding electrical and physical properties. Mono-layers can be stacked on each other to form a 2D material layer that includes individual monolayers. In some embodiments, individual monolayers of graphene, thin layers of black phosphorus (also known as phosphorene), graphene analogues (such as silicene, gemanene, stannene, etc.), and/or boron nitride can be stacked to create the 2D material layer. In some embodiments, the 2D material layer 53 can include transition metal dichalcogenides (TMDs). The TMDs can have a general formula of MX₂, where M denotes a transition metal from, for example, periodic table column {IVB, VB, VIB} (e.g., molybdenum (Mo), tungsten (W), niobium (Nb), haftnium (Hf), or tantalum (Ta)), and X denotes an element from the group of {sulfur (S), selenium (Se), or tellurium (Te)}. In some embodiments, the 2D material layer 53 can be formed using suitable deposition methods, including but not limited to epitaxial growth, atomic layer deposition (ALD), CVD, PEVCD, molecular beam epitaxy (MBE), or metal deposition with subsequent chemical reaction. In some embodiments, forming the 2D material layer 53 can include a Langmuir-Blodgett process. In some embodiments, forming the 2D material layer 53 can include deposition processes and subsequent annealing processes to improve the material quality by increasing the domain size and reducing the defects.

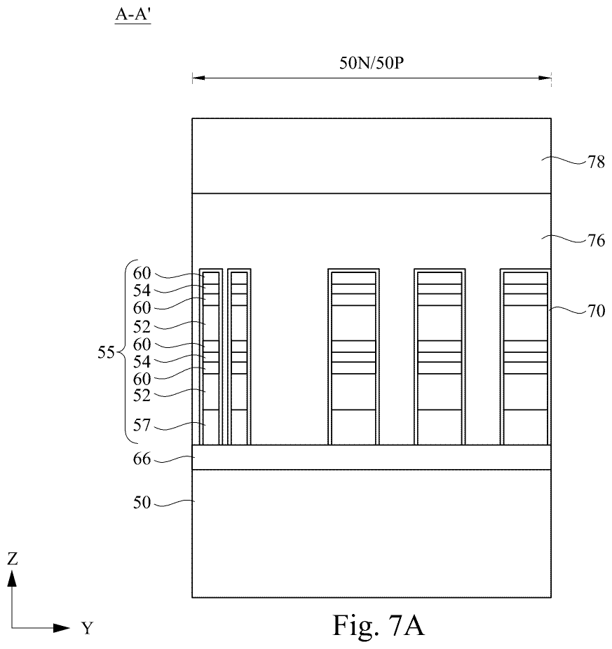

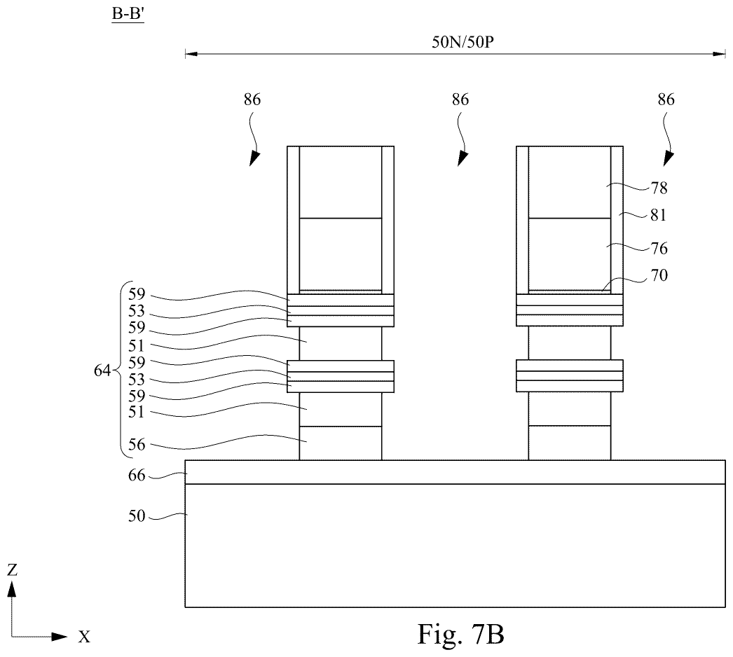

The protective layer 59 and the dielectric layer 51 may be materials having a high-etch selectivity to one another. As such, the dielectric layer 51 may be removed without damaging the 2D material layers 53 capping by the protective layer 59, thereby allowing the 2D material layers 53 to be released to form channel regions of the nano-FETs. Specifically, the protective layer 59 can serve multiple protective during various etching and processing steps, such as those shown in FIGS. 7A, 7B, 12A, 12B, and 12C. The protective layer 59 can shield the underlying 2D material layers 53 during etching processes. The protective layer 59 can act as a barrier against etchants and other chemical processes that could otherwise degrade or unintentionally remove the 2D material layers 53. In some embodiments, the protective layer 59 can prevent unwanted chemical reactions between the 2D materials and other substances used in later processing steps. This isolation can help maintain the purity and electronic properties of the 2D materials. By protecting the integrity of the 2D material layers during manufacturing steps, the protective layer 59 can enhance the overall reliability of the semiconductor devices. Therefore, as the device features are etched deeper to form structures like trenches or vias, the protective layer 59 can ensure that the etching does not extend into the 2D material layers, preserving their functionality as part of the device's active regions. In processes aimed at releasing or defining the channel areas, the protective layer 59 can prevent over-etching or damage to the 2D materials.

In some embodiments, the protective layer 59 may be formed of metal oxide. In some embodiments, the protective layer 59 may be formed of a material having a dielectric constant greater than about 9 (e.g., high dielectric constant (high-k) material). For example, the protective layer 59 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The protective layer 59 may be formed of a homogenous material, or may have a composite structure including more than one layer. In some embodiments, the protective layer 59 can be made of a same material as the etch stop layer 66. In some embodiments, the protective layer 59 can be made of a different material than the etch stop layer 66. In some embodiments, the protective layer 59 can be formed using suitable deposition methods, including but not limited to chemical vapor deposition (CVD), plasma-enhanced chemical vapor deposition (PECVD), atomic layer deposition (ALD), plasma-enhanced atomic layer deposition (PEALD), or the like.

In some embodiments, as shown in FIG. 2B, a hard mask layer 68 can be formed over the multi-layer stack 64, and an additional dielectric layer 51 can be formed between the protective layer 59 and the hard mask layer 68. In some embodiments, the hard mask layer 68 can serve as a durable, selective barrier during the etching of underlying materials. In some embodiments, the hard mask layer 68 can serve as an etch stop for certain etching phases, allowing for high selectivity in etching processes and achieving the patterns without damaging the nanostructures.

The hard mask layer 68 may comprise any suitable insulating material, such as an oxide, a nitride, and oxynitride, and oxycarbonitride, or the like. In some embodiments, the hard mask layer 68 may be formed of metal oxide. In some embodiments, the hard mask layer 68 may be formed of a material having a dielectric constant greater than about 9 (e.g., high dielectric constant (high-k) material). For example, the protective layer 59 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. In some embodiments (not separately illustrated), the hard mask layer 68 may be a multi-layer structure. The hard mask layer 68 may be formed over the nanostructures 55 using an acceptable process(es) such as thermal oxidation, physical vapor deposition (PVD), CVD, ALD, combinations thereof, or the like. In some embodiments. the hard mask layer 68 can have a thickness T4 thicker than the thickness T2 of the protective layer 59.

Reference is made to FIGS. 3A-3C. Nanostructures 55 are formed in the multi-layer stack 64 and over the etch stop layer 66, by etching trenches 58 in the multi-layer stack 64 to expose the etch stop layer 66. The etching may be any acceptable etch process, such as a reactive ion etch (RIE), neutral beam etch (NBE), the like, or a combination thereof. The etching may be anisotropic. The nanostructures 55 may be patterned by any suitable method. For example, the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures 55.

Forming the nanostructures 55 by etching the multi-layer stack 64 may further define nanostructures 52 from the dielectric layers 51, nanostructures 54 from the 2D material layers 53, a nanostructure 57 from the dielectric layer 56, and the nanostructures 60 from the protective layers 59. The nanostructures 52, 54, 57, and 59 can be collectively referred to as the nanostructures 55. In some embodiments, the nanostructure 55 can be interchangeable referred to as a fin structure. In some embodiments, widths of the nanostructure 55 in the n-type region 50N may be greater or thinner than the nanostructure 55 in the p-type region 50P. In other embodiments, the nanostructures 55 may have tapered sidewalls such that a width of each of the nanostructures 55 continuously increases in a direction towards the etch stop layer 66. In such embodiments, each of the nanostructures 55 may have a different width and be trapezoidal in shape. Under the structure shown in FIG. 2B, nanostructures 69 (see FIG. 3B) can be formed over the multi-layer stack 64, by etching trenches 58 that expose the etch stop layer 66, and an additional nanostructure 52 can be formed between the nanostructure 52 and the nanostructure 59.

In some embodiments, the etch stop layer 66 can act as a barrier that selectively stops the etching process at a predefined depth, ensuring that the etching does not proceed beyond a certain point, maintaining the integrity of the underlying substrate 50 or other layers. In some embodiments, in the absence of the etch stop layer 66, different pattern densities (sparse vs. dense) could result in non-uniform etching depths due to variations in local etch rates. Further etching during steps like the sheet release etch (FIGS. 12A-12C) could exacerbate the depth differences, leading to potential damage to the substrate 50, which in turn manifests as pattern collapse or compromised structural integrity in some areas. The etch stop layer 66 can provide a consistent stopping point for the etching process, which in turn helps achieve uniform etch depths across various pattern densities. By serving as a physical barrier, the etch stop layer 66 can prevent the etchant from penetrating deeper into the substrate, avoiding over-etching that could lead to structural weaknesses or defects like pattern collapse. Therefore, with the etch stop layer 66 in place, the fabrication process can become more reliable as it reduces the variability in etching depths, leading to more consistent and repeatable manufacturing outcomes.

While the etch stop layer 66 can resist the etching chemicals and processes used to pattern other materials, it may still undergo some degree of etching, albeit at a much slower rate. As a result of this selective consumption, as shown in FIG. 3C, the thickness T1 of the etch stop layer 66 can vary across the wafer. Specifically, the portions of the etch stop layer 66 that are directly exposed to the etching process might thin out more compared to the regions that are shielded by the nanostructures 55, leading to a scenario where the thickness T1 of the etch stop layer 66 beneath the nanostructures 55 can be greater than the thickness T1 in areas not covered by nanostructures 55.

Reference is made to FIGS. 4A and 4B. Dummy gates are formed over and along sidewalls of the nanostructures 55 and the etch stop layer 66. To form the dummy gates, first, a dummy dielectric layer is formed on the etch stop layer 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the nanostructures 54. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the nanostructures 55 for illustrative purposes only. In some embodiments, the dummy gate dielectrics 70 may be deposited such that the dummy gate dielectrics 70 covers the etch stop layer 66, such that the dummy gate dielectrics 70 extends between the dummy gates 76 and the etch stop layer 66.

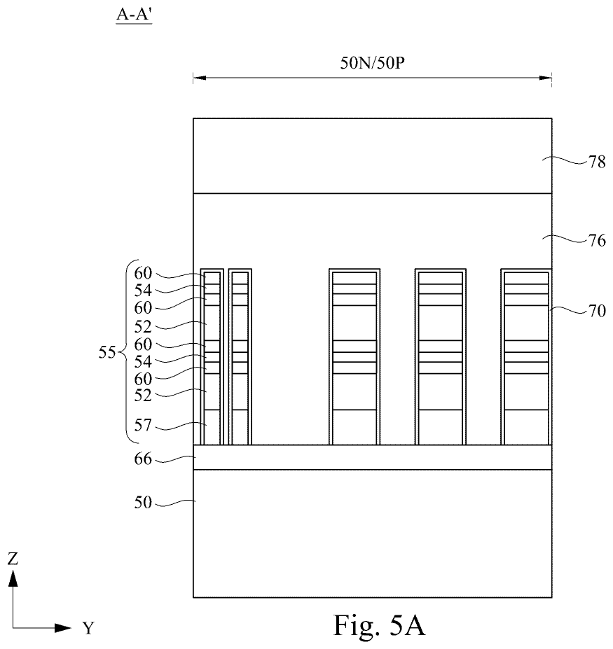

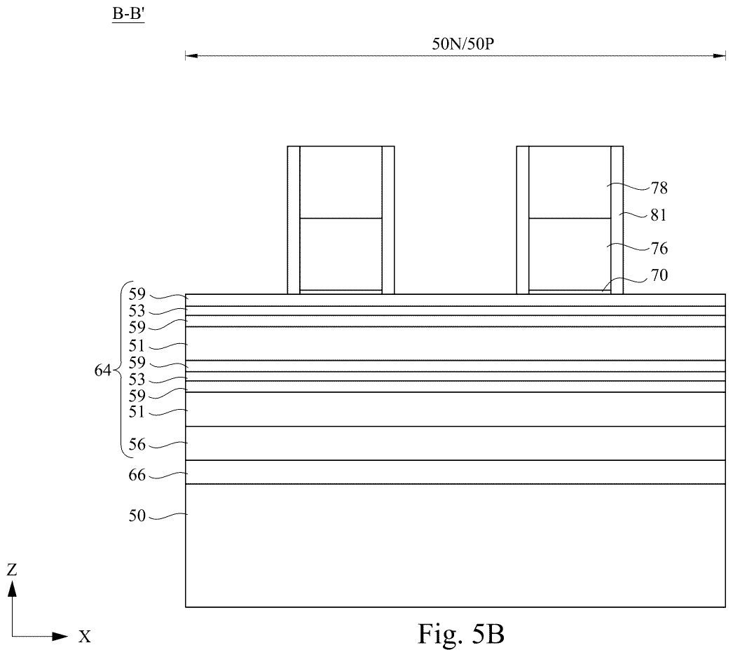

Reference is made to FIGS. 5A and 5B. Gate spacers 81 can be formed over the nanostructures 55 and the etch stop layer 66, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). It is noted that the previous disclosure generally describes a process of forming spacers. Other processes and sequences may be used. For example, fewer or additional spacers may be utilized, different sequence of steps may be utilized, additional spacers may be formed and removed, and/or the like.

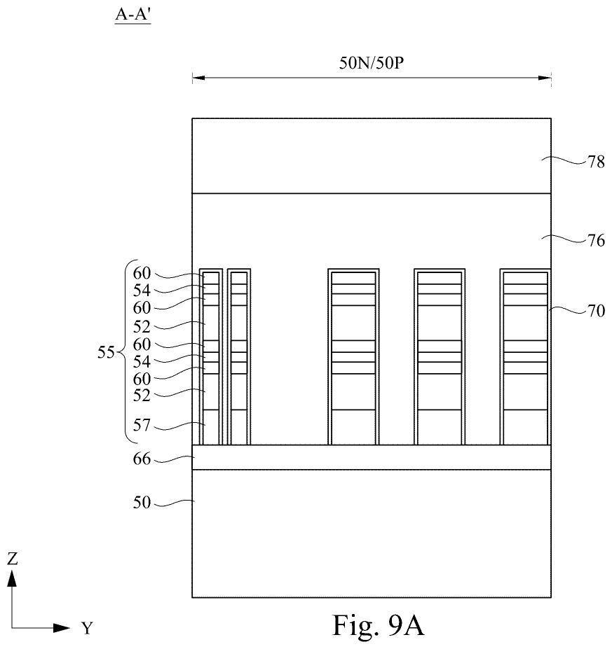

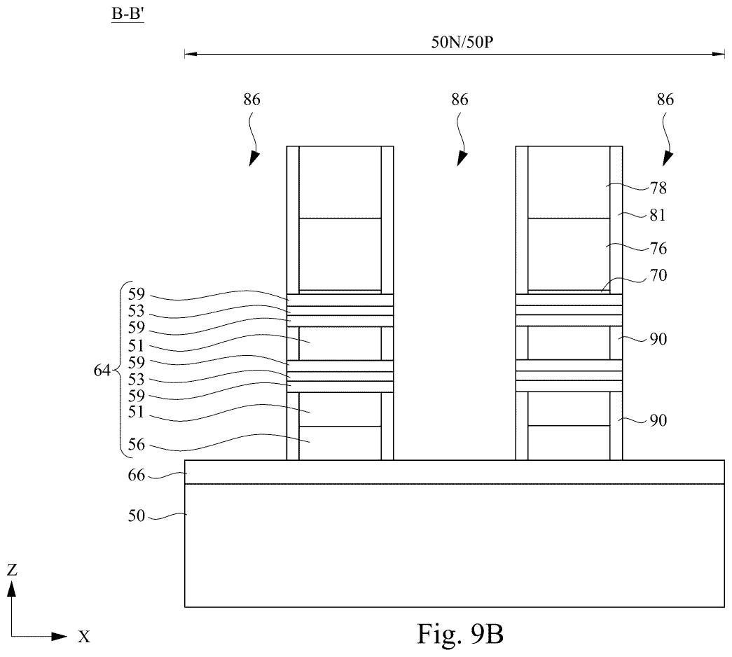

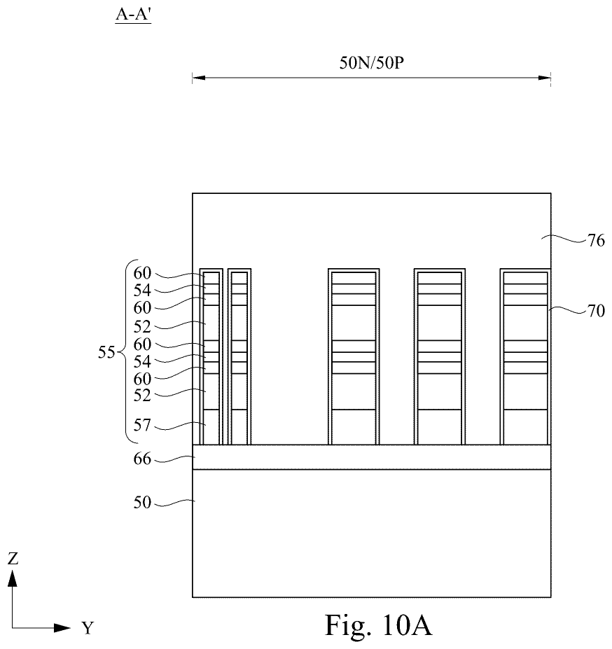

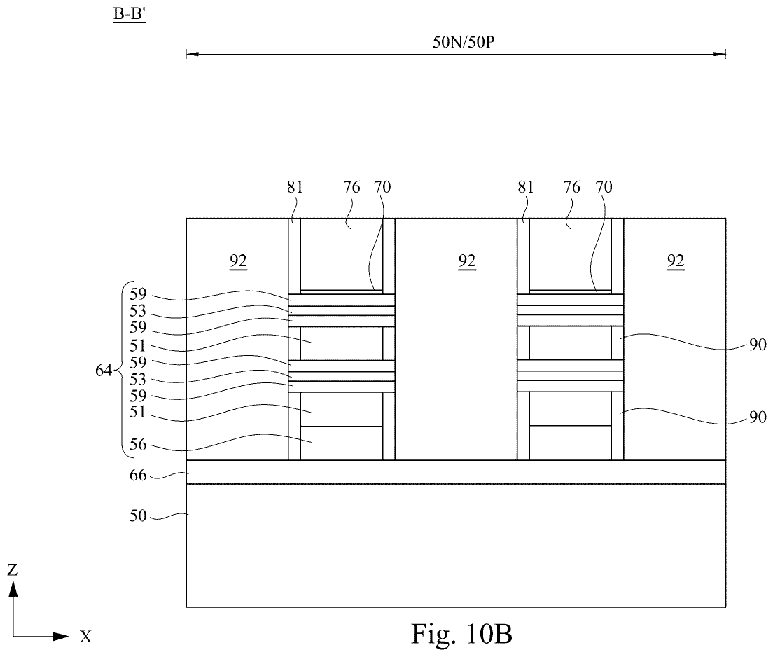

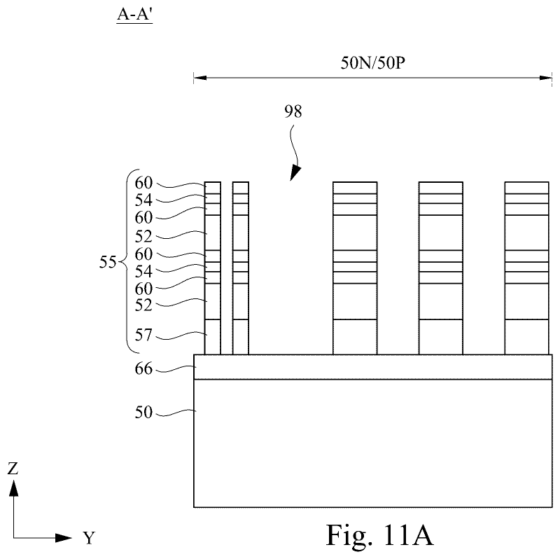

Reference is made to FIGS. 6A-6C. Recesses 86 can be formed in the nanostructures 55 to expose the etch stop layer 66. In some embodiments, end portions of the nanostructure 54 that are exposed from the recesses 86 can be considered as source/drain regions. In some embodiments, the end portions of the nanostructure 54 can be portions that vertically overlap with the inner spacers 90 (see FIG. 9B). Subsequently, source/drain regions 92 (see FIGS. 10A and 10B) will be subsequently formed in the recesses 86. The recesses 86 may extend through the nanostructures 52, 54, 57, and 60 and stop at the etch stop layer 66. As illustrated in FIG. 7B, a top surface of the etch stop layer 66 is exposed in the recesses 86. In some embodiments, the etch stop layer 66 may be etched such that bottom surfaces of the recesses 86 are disposed below the topmost position of the etch stop layer 66. The recesses 86 may be formed by etching the nanostructures 52, 54 ,57, and 60 using anisotropic etching processes, such as RIE, NBE, or the like. The gate spacers 81 and the masks 78 mask portions of the nanostructures 52, 54, 57, and 60 during the etching processes used to form the recesses 86. A single etch process or multiple etch processes may be used to etch each layer of the nanostructures 52, 54, 57, and 60. Timed etch processes may be used to stop the etching of the recesses 86 after the recesses 86 reach a desired depth.

Reference is made to FIGS. 7A-9B. Inner spacers 90 (see FIG. 9B) can be formed on sidewalls of the etched portions of the nanostructures 54, e.g., those sidewalls exposed by the recesses 86. As will be subsequently described in greater detail, source/drain regions 92 (see FIG. 10B) will be subsequently formed in the recesses 86, and the nanostructures 54 will be subsequently replaced with corresponding gate structures, such that the inner spacers 90 can act as isolation features between the subsequently formed source/drain regions 92 and the subsequently formed gate structures. Further, the inner spacers 90 may be used to substantially prevent damage to the subsequently formed source/drain regions 92 by subsequent etching processes, such as etching processes used to subsequently remove the nanostructures 54. In some embodiments, the inner spacers 90 can be interchangeably referred to lower gate spacers.

As shown in FIGS. 7A and 7B, as an example to form the inner spacers 90, the recesses 86 can be laterally expanded. Specifically, portions of the sidewalls of the nanostructures 52 and 57 exposed by the recesses 86 may be recessed. Although sidewalls of the nanostructures 52 are illustrated as being straight, the sidewalls may be concave or convex. The sidewalls may be recessed by any acceptable etching process, such as one that is selective to the material of the nanostructures 52 and 57 (e.g., selectively etches the material of the nanostructures 52 and 57 at a faster rate than the material of the nanostructures 54). The etching may be isotropic. In some embodiments, the etching process may be a dry etch using tetramethylammonium hydroxide (TMAH), ammonium hydroxide (NH₄OH), or the like. In some embodiments, the etching process may be a dry etch using a fluorine-based gas such as hydrogen fluoride (HF) gas or carbon tetrafluoride (CF₄) gas. In some embodiments, the same etching process may be continually performed to both form the recesses 86 and recess the sidewalls of the nanostructures 52 and 57.

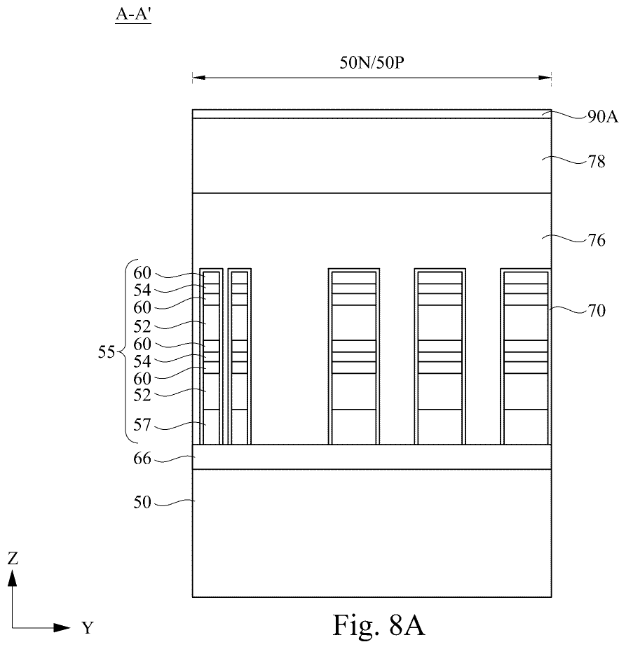

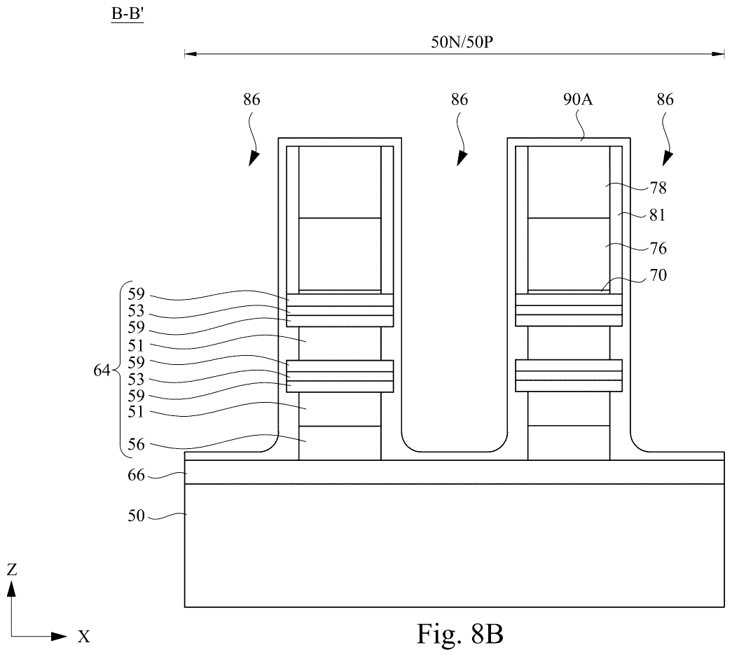

As shown in FIGS. 8A and 8B, the inner spacers 90 (see FIG. 9B) can then be formed by conformally forming an insulating material 90A and subsequently etching the insulating material 90A. The insulating material 90A may be silicon nitride or silicon oxynitride, although any suitable material, such as low-dielectric constant (low-k) materials having a k-value less than about 3.5, may be utilized. In some embodiments, the insulating material 90A may have a higher K (dielectric constant) value than the gate spacers 81. In some embodiments, the material of the insulating material 90A can be selected from a group including SiO₂, Si₃N₄, SiON, SiOC, SiOCN base dielectric material, air gap, or combinations thereof. The insulating material 90A may be deposited by a conformal deposition process, such as ALD, CVD, or the like.

As shown in FIGS. 9A and 9B, after the deposition of the insulating material 90A, an anisotropic etching process may be performed to trim the deposited insulating material 90A, such that portions of the insulating material 90A on the etched sidewalls of the nanostructures 52 and 57 can be left. After the trimming process, the remaining portions of the insulating material 90A can be denoted as the inner spacers 90. In some embodiments, the etching process may be a dry etch such as a RIE, a NBE, or the like. Although outer sidewalls of the inner spacers 90 are illustrated as being flush with respect to the sidewalls of the gate spacers 81, the outer sidewalls of the inner spacers 90 may extend beyond or be recessed from the sidewalls of the gate spacers 81. Moreover, although the sidewalls of the inner spacers 90 are illustrated as being straight, the sidewalls of the inner spacers 90 may be concave or convex.

Reference is made to FIGS. 10A and 10B. Source/drain regions 92 can be formed in the recesses 86. In some embodiments, the source/drain regions 92 can be formed on the exposed nanostructures 54. The source/drain regions 92 can be physically and electrically connected to the nanostructures 54 and provide electrical access to external interconnections or devices. In some embodiments, the source/drain regions 92 can include metallic material such as, for example, platinum, nickel, cobalt, tantalum, titanium, platinum, erbium, palladium, aluminum, and/or tungsten. In some embodiments, the source/drain regions 92 can be deposited using conventional processes such as physical vapor deposition (PVD), CVD, PECVD, ALD, atmospheric pressure chemical vapor deposition (APCVD), low-pressure CVD) (LPCVD), high density plasma CVD (HDPCVD), or atomic layer CVD (ALCVD).

Subsequently, a removal process is performed to level the top surfaces of the source/drain regions 92 with the top surfaces of the dummy gates 76. In some embodiments, a planarization process such as a chemical mechanical polish (CMP), an etch-back process, combinations thereof, or the like may be utilized. The planarization process may also remove the masks 78 on the dummy gate 76, and portions of the gate spacers 81 along sidewalls of the masks 78. After the planarization process, the top surfaces of the source/drain regions 92, the gate spacers 81, and the dummy gate 76 can be coplanar (within process variations). In some embodiments, the masks 78 remain, and the planarization process levels the top surfaces of the source/drain regions 92 with the top surfaces of the masks 78.

Reference is made to FIGS. 11A and 11B. The dummy gates 76 can be removed in an etching process, so that recesses 98 can be formed. In some embodiments, the dummy gates 76 can be removed by an anisotropic dry etch process. For example, the etching process may include a dry etch process using reaction gas(es) that selectively etch the dummy gates 76 at a faster rate than the source/drain regions 92 and the gate spacers 81. During the removal, the dummy gate dielectrics 70 may be used as etch stop layers when the dummy gate 76 are etched. The dummy gate dielectrics 70 are then removed. Each recess 98 can expose and/or overlies portions of the channel regions. Portions of the nanostructures 54 which act as the channel regions are disposed between adjacent pairs of the source/drain regions.

Reference is made to FIGS. 12A and 12B. The remaining portions of the nanostructures 52 and 57 can be then removed to expand the recesses 98. The remaining portions of the nanostructures 52 and 57 can be removed by any acceptable etching process that selectively etches the material of the nanostructures 52 and 57 at a faster rate than the material of the nanostructures 60 and the etch stop layer 66. The etching may be isotropic. For example, when the nanostructures 52 and 57 can be formed of silicon nitride and/or silicon oxide and the nanostructures 60 and 66 can be formed of high-k dielectric material, the etching process may be a dry etch using carbon tetrafluoride (CF₄) gas or the like. In some embodiments, the removing of the remaining portions of the nanostructures 52 and 57 can be interchangeably referred to as a channel releasing process.

In some embodiments, the etch stop layer 66 can ensure precision and control during the sheet release etch steps. The etch stop layer 66 can provide a uniform stopping point for the etching agents, ensuring that the etching process does not proceed too deeply into the substrate 50, which in turn allows for maintaining consistent etch depths across the wafer, in areas with varying pattern densities. By serving as a barrier, the etch stop layer 66 can protect the underlying substrate 50 from being damaged or inadvertently etched away. The etch stop layer 66 can offer high selectivity during the etching process, meaning it can effectively resist the etch chemistry while allowing the surrounding materials to be removed. The etch stop layer 66 can prevent over-etching in sparse patterned portions where etchant could otherwise penetrate deeper, causing excessive material removal that could lead to pattern collapse or structural failures. In areas with denser patterns, where etch rates might be slower due to reduced exposure to etchants, the etch stop layer can ensure that etching stops at a consistent depth, preventing insufficient etching which could result in incomplete pattern transfer or functional issues in subsequent layers. In some embodiments, without the protective boundary provided by the etch stop layer 66, the etching process could remove material from the substrate 50. This uncontrolled removal could lead to weakened structures that are prone to collapse under mechanical stress or during further processing.

In some semiconductor manufacturing processes, as shown in FIGS. 12A and 12B, during the OD etch, the etch stop layer 66 may experience partial consumption, leading to the formation of recesses 66r in the etch stop layer 66, especially in areas where the pitch between patterns is relatively wide. The etch stop layer 66 can be composed of materials that are resistant to the etching chemicals used to remove other layers or materials above it. However, during extensive or aggressive etching processes, even robust materials like high-k dielectrics (e.g., hafnium oxide) can be partially consumed. In some embodiments, this consumption can be more pronounced in areas where the etch stop layer 66 is more exposed to the etchant, which may correspond to regions with wider pitches between patterns. In regions where the pattern pitch is wide, the etch stop layer 66 may have less protection from overlying materials, making these areas more vulnerable to etchant exposure. As the etch stop layer 66 is partially consumed in these regions, it can form recesses 66r, localized areas where the thickness of the etch stop layer is reduced compared to surrounding areas.

As shown in FIG. 12B, after the channel release step, the nanostructures 69 being part of the hard mask layer or additional structural elements can be added to provide mechanical stability, protection, or to serve as a mask during further etching or doping processes. In some embodiments, the nanostructures 69 positioned above the active channel nanostructures 54 can provide protection against contaminants and physical damage during subsequent processing steps, such as etching. After the channel release step, the nanostructures 69 remain intact and are positioned above the nanostructures 54, which form the active channel regions of the device.

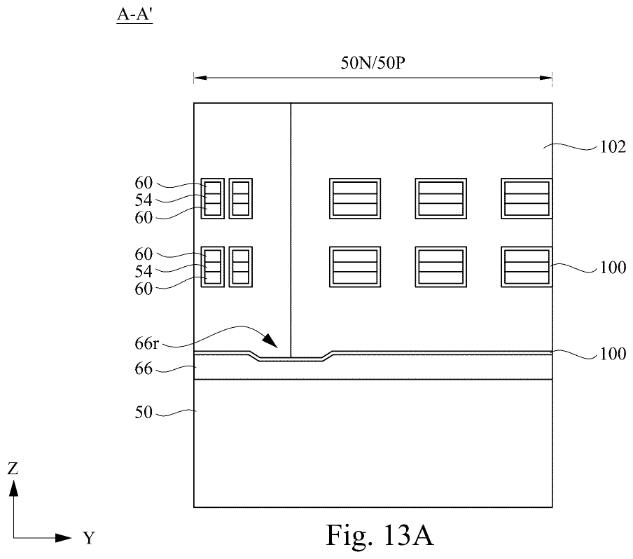

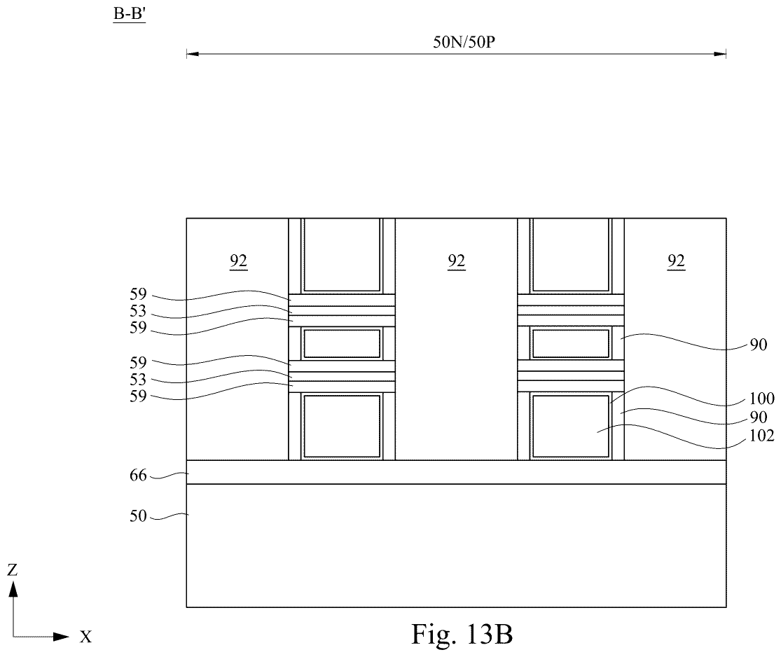

Reference is made to FIGS. 13A and 13B. Gate dielectric layers 100 and gate electrodes 102 can be formed for replacement gates. The gate dielectric layers 100 can be deposited conformally in the recesses 98. The gate dielectric layers 100 may be formed on top surfaces of the etch stop layer 66, on top surfaces, sidewalls, and bottom surfaces of the nanostructures 54, and on the inward sidewalls of the inner spacers 90 (if exposed). The gate dielectric layers 100 may also be deposited on top surfaces of the source/drain regions 92 and the gate spacers 81.

In some embodiments, the gate dielectric layers 100 can include one or more dielectric layers, such as an oxide, a metal oxide, the like, or combinations thereof. For example, in some embodiments, the gate dielectric layers 100 may include a silicon oxide layer and a metal oxide layer over the silicon oxide layer. In some embodiments, the gate dielectric layers 100 can include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 can be deposited over the gate dielectric layers 100, respectively, and fill the remaining portions of the recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 13A and 13B, the gate electrodes 102 may comprise any number of liner layers, any number of work function tuning layers, and a fill material. Any combination of the layers which make up the gate electrodes 102 may be deposited in the n-type region 50N between adjacent ones of the nanostructures 54 and between the nanostructure 54 and the etch stop layer 66, and may be deposited in the p-type region 50P between adjacent ones of the nanostructures 54.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the recesses 98, a planarization process, such as a CMP, may be performed to remove the excess portions of the gate dielectric layers 100 and the material of the gate electrodes 102, which excess portions are over the top surface of the source/drain regions 92 and the gate spacers 81. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

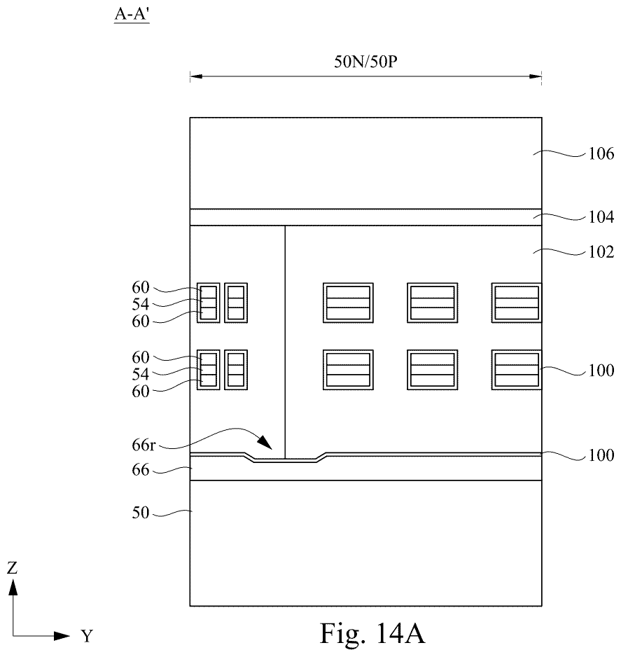

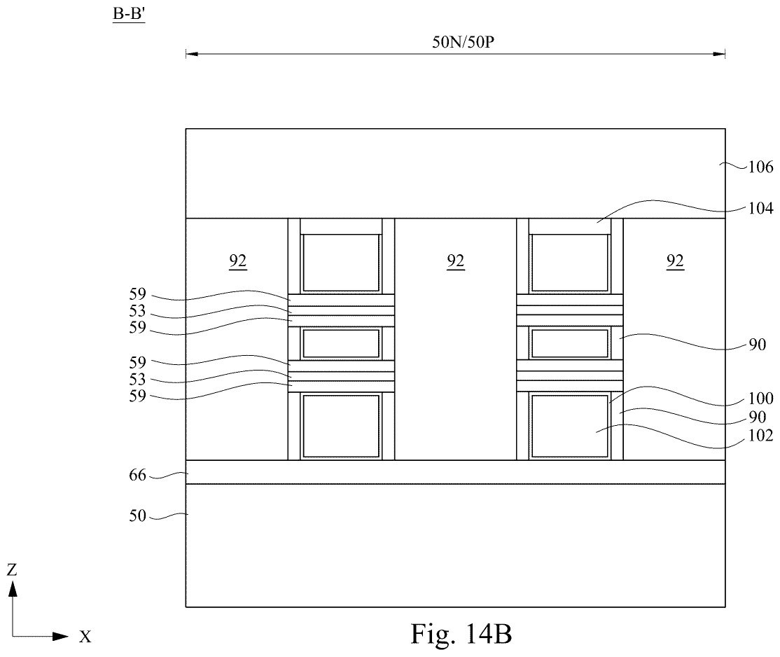

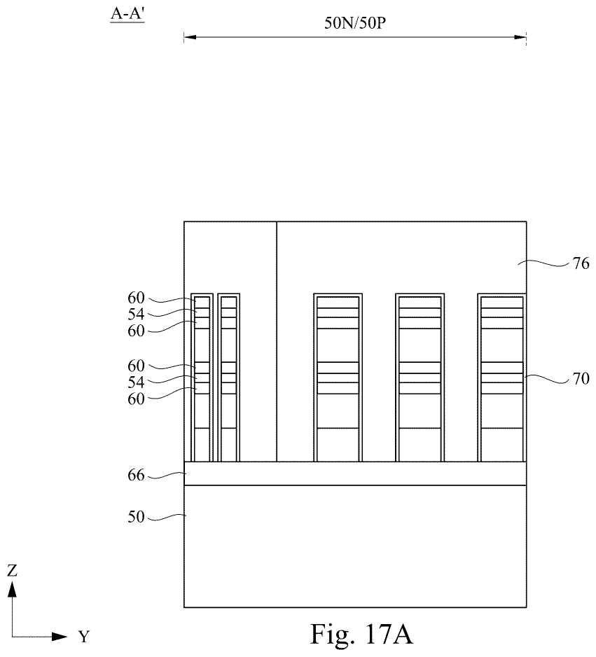

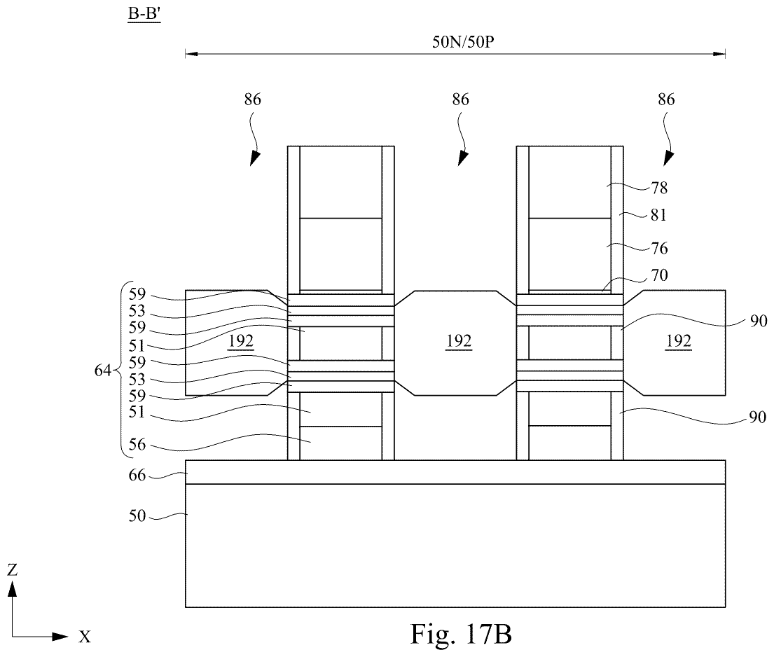

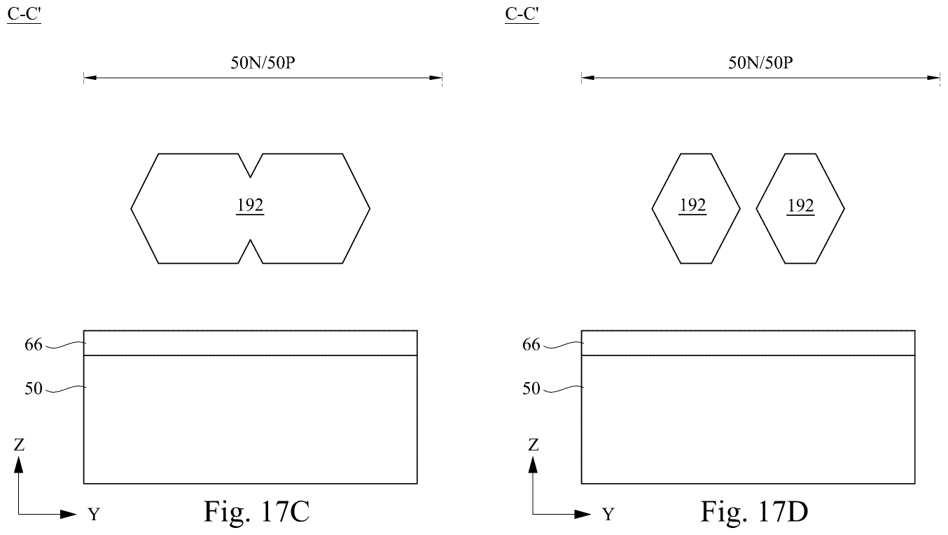

Reference is made to FIGS. 14A and 14B. The gate structure (including the gate dielectric layers 100 and the corresponding overlying gate electrodes 102) can be recessed, so that a recess is formed directly over the gate structure and between opposing portions of gate spacers 81. A gate mask 104 including one or more layers of dielectric material, such as silicon nitride, silicon oxynitride, or the like, is filled in the recess, followed by a planarization process to remove excess portions of the dielectric material extending over the source/drain regions 92 and the gate spacers 81. Subsequently formed gate contacts (such as the gate contacts 114, discussed below with respect to FIG. 17B) penetrate through the gate mask 104 to contact the top surface of the recessed gate electrodes 102.

As further illustrated, a dielectric layer 106 can deposited over the source/drain regions 92, the gate spacers 81, and the gate mask 104. In some embodiments, the dielectric layer 106 is a flowable film formed by FCVD. In some embodiments, the dielectric layer 106 can be formed of a dielectric material such as PSG, BSG, BPSG, USG, or the like, and may be deposited by any suitable method, such as CVD, PECVD, or the like.

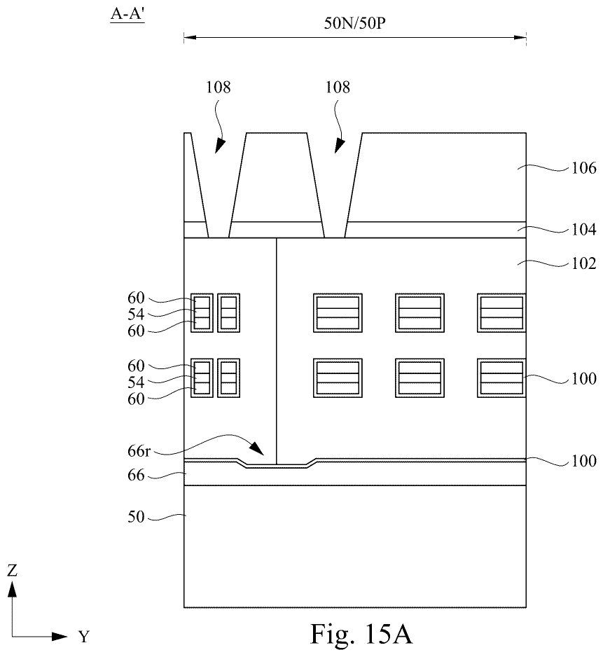

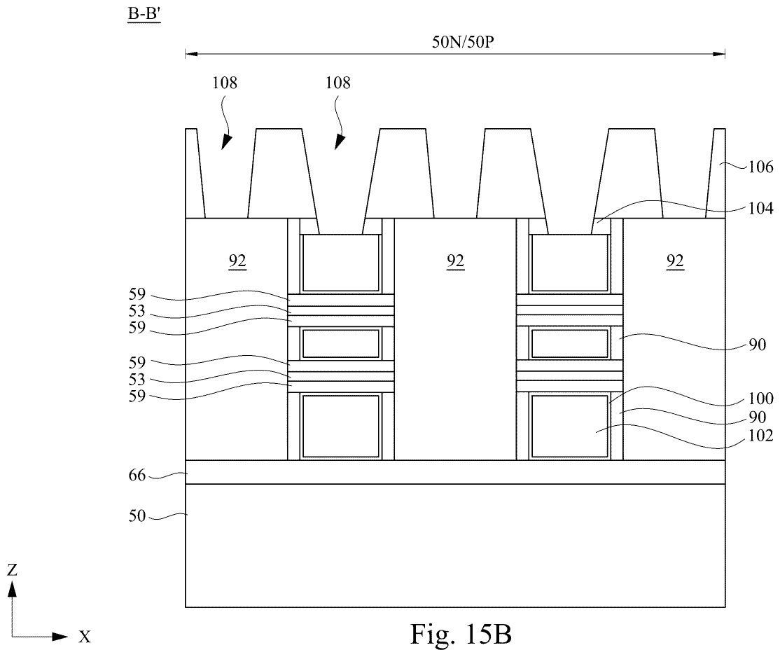

Reference is made to FIGS. 15A and 15B. The dielectric layer 106 and the gate masks 104 can be etched to form recesses 108 exposing surfaces of the source/drain regions 92 and/or the gate structure. The recesses 108 may be formed by etching using an anisotropic etching process, such as RIE, NBE, or the like. In some embodiments, the recesses 108 may be etched through the dielectric layer 106 using a first etching process; may be etched through the gate masks 104 using a second etching process different than the first etching process. A mask, such as a photoresist, may be formed and patterned over the dielectric layer 106 to mask portions of the dielectric layer 106 from the first etching process and the second etching process. In some embodiments, the etching process may over-etch, and therefore, the recesses 108 can extend into the source/drain regions 92 and/or the gate structure, and a bottom of the recesses 108 may be level with (e.g., at a same level, or having a same distance from the substrate), or lower than (e.g., closer to the substrate) the source/drain regions 92 and/or the gate structure. Although FIG. 15B illustrate the recesses 108 as exposing the source/drain regions 92 and the gate structure in a same cross section, in various embodiments, the source/drain regions 92 and the gate structure may be exposed in different cross-sections, thereby reducing the risk of shorting subsequently formed contacts.

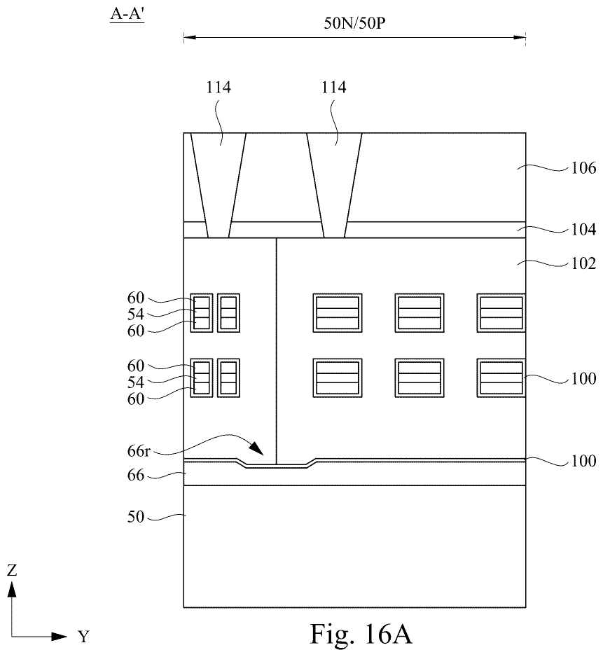

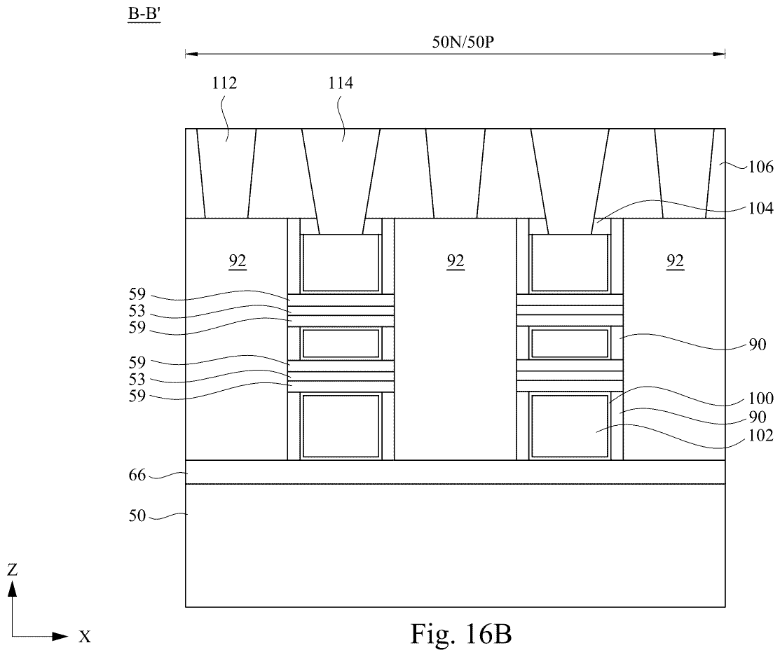

Reference is made to FIGS. 16A and 16B. Contacts 112 and 114 (may also be referred to as contact plugs) can be formed in the recesses 108. The contacts 112 and 114 may each may include one or more layers, such as barrier layers, diffusion layers, and fill materials. For example, in some embodiments, the contacts 112 and 114 each can include a barrier layer and a conductive material, and is electrically coupled to the underlying conductive feature (e.g., gate electrode 102 in the illustrated embodiment). The contacts 114 can be electrically coupled to the gate electrode 102 and may be referred to as gate contacts, and the contacts 112 can be electrically coupled to the source/drain regions 92 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the dielectric layer 106.

Reference is made to FIGS. 17A-19C. FIGS. 17A-19C illustrate the cross-sectional views of intermediate stages in the formation of a semiconductor structure in accordance with some embodiments. FIGS. 17A, 18A, and 19A illustrate reference cross-section A-A′ illustrated in FIG. 1. FIGS. 17B, 18B, and 19B illustrate reference cross-section B-B′ illustrated in FIG. 1. FIGS. 17C, 17D, 18C, and 19C illustrate reference cross-section C-C′ illustrated in FIG. 1. Operations for forming semiconductor structure prior to the structure shown in FIGS. 17A-19C are substantially the same as the operations for forming the semiconductor structure shown in FIGS. 2A-9B, and reference may be made to the foregoing paragraphs for the related detailed descriptions and such descriptions are not provided again herein. While FIGS. 17A-19C show an embodiment of the semiconductor structure with different layout profiles than the those in FIGS. 2A-9B. The present disclosure may repeat reference numerals and/or letters in the various examples. This repetition is for the purpose of simplicity and clarity and does not in itself dictate a relationship between the various embodiments and/or configurations discussed.

Reference is made to FIGS. 17A-17D. Source/drain regions 192 can be formed in the first recesses 86. As illustrated, the source/drain regions 192 can be formed in the first recesses 86 such that each dummy gate 76 is disposed between respective neighboring pairs of the source/drain regions 192. In some embodiments, the gate spacers 81 can be used to separate the source/drain regions 192 from the dummy gates 76 and the inner spacers 90 can be used to separate the source/drain regions 192 from the nanostructures 52 by an appropriate lateral distance so that the source/drain regions 192 do not short out with subsequently formed gates of the resulting nano-FETs.

In some embodiments, the source/drain regions 192 in the n-type region 50N, e.g., the NMOS region, may be formed by masking the p-type region 50P, e.g., the PMOS region. Then, the source/drain regions 192 can be epitaxially grown in the recesses 86 in the n-type region 50N. The source/drain regions 192 may include any acceptable material appropriate for n-type nano-FETs. In some embodiments, the source/drain regions 192 in the n-type region 50N may include materials exerting a tensile strain on the nanostructures 54, such as silicon, silicon carbide, phosphorous doped silicon carbide, silicon phosphide, or the like.

In some embodiments, the source/drain regions 192 in the p-type region 50P, e.g., the PMOS region, may be formed by masking the n-type region 50N, e.g., the NMOS region. Then, the source/drain regions 192 In some embodiments, epitaxially grown in the recesses 86 in the p-type region 50P. The source/drain regions 192 may include any acceptable material appropriate for p-type nano-FETs. In some embodiments, the source/drain regions 192 in the p-type region 50P may include materials exerting a compressive strain on the nanostructures 54, such as silicon-germanium, boron doped silicon-germanium, germanium, germanium tin, or the like.

In some embodiments, the source/drain regions 192 may be implanted with dopants to form source/drain regions, followed by an anneal. In some embodiments, the source/drain regions 192 may have an impurity concentration of between about 1×10¹⁹ atoms/cm³ and about 1×10²¹ atoms/cm³. In some embodiments, the source/drain regions 192 may be in situ doped during growth.

FIGS. 17C and 17D illustrate exemplary detailed views of various elements of FIG. 17B, including the nanostructures 52 and 54, the inner spacers 90, and the source/drain regions 192. As illustrated, after initially forming over and along the sidewalls of the nanostructures 54, portions of the source/drain regions 192 converge and form over and along the outward sidewalls of the inner spacers 90. As a result of the epitaxy processes used to form the source/drain regions 192 in the n-type region 50N and the p-type region 50P, upper surfaces of the source/drain regions 192 have facets which expand laterally outward beyond sidewalls of the nanostructures 55. In some embodiments, these facets cause adjacent source/drain regions 192 of a same nano-FET to merge as illustrated by FIG. 17C. In other embodiments, adjacent source/drain regions 192 remain separated after the epitaxy process is completed as illustrated by FIG. 17D. In some embodiments, the source/drain regions 192 can have various cross-section shapes such as, for example, square, rectangle, pentagon, and/or other suitable shapes thereof.

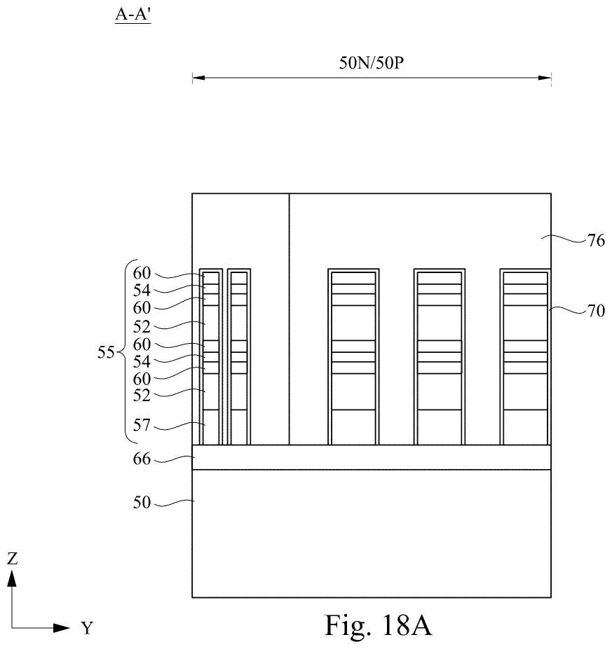

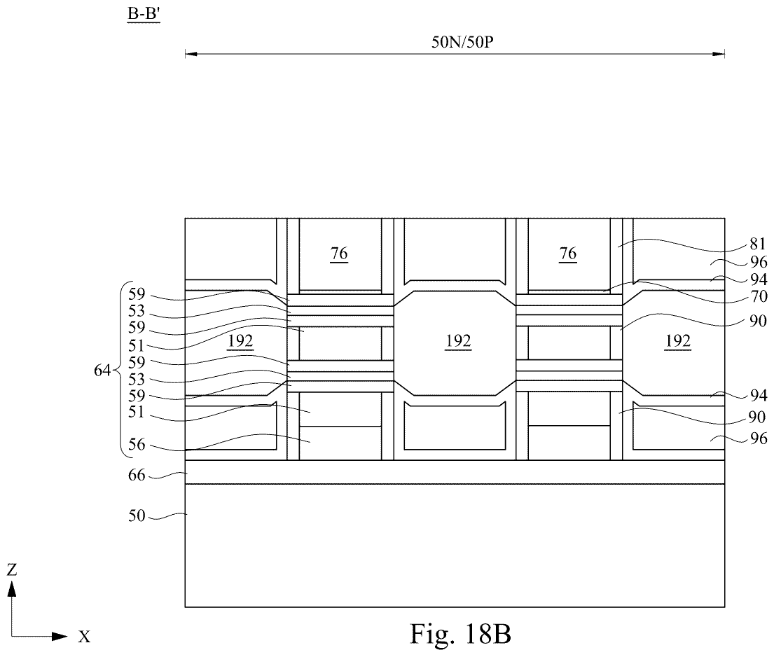

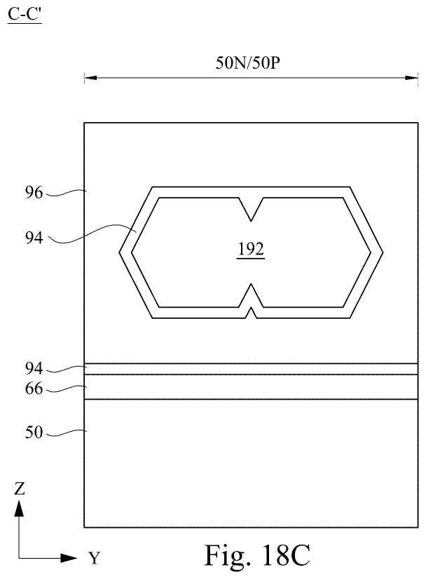

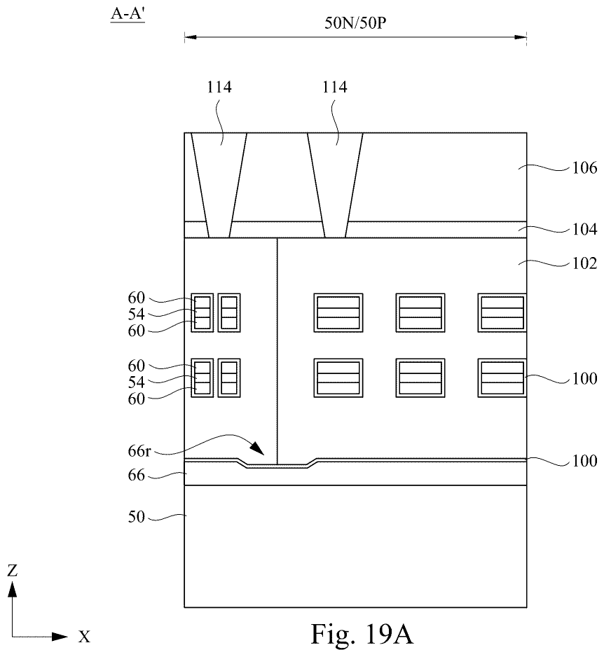

Reference is made to FIGS. 18A-18C. An interlayer dielectric (ILD) layer 96 can be deposited over the structure illustrated in FIGS. 17A-17D. The ILD layer 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 can be disposed between the ILD layer 96 and the source/drain regions 192, the masks 78, and the gate spacers 81. The CESL 94 may include a dielectric material, such as, silicon nitride, silicon oxide, silicon oxynitride, or the like, having a different etch rate than the material of the overlying ILD layer 96.

After the ILD layer 96 is deposited, a planarization process, such as a CMP, may be performed to level the top surface of the ILD layer 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the ILD layer 96 are level within process variations. Accordingly, the top surfaces of the dummy gates 76 can be exposed through the ILD layer 96. In some embodiments, the masks 78 may remain, in which case the planarization process levels the top surface of the ILD layer 96 with top surface of the masks 78 and the gate spacers 81.

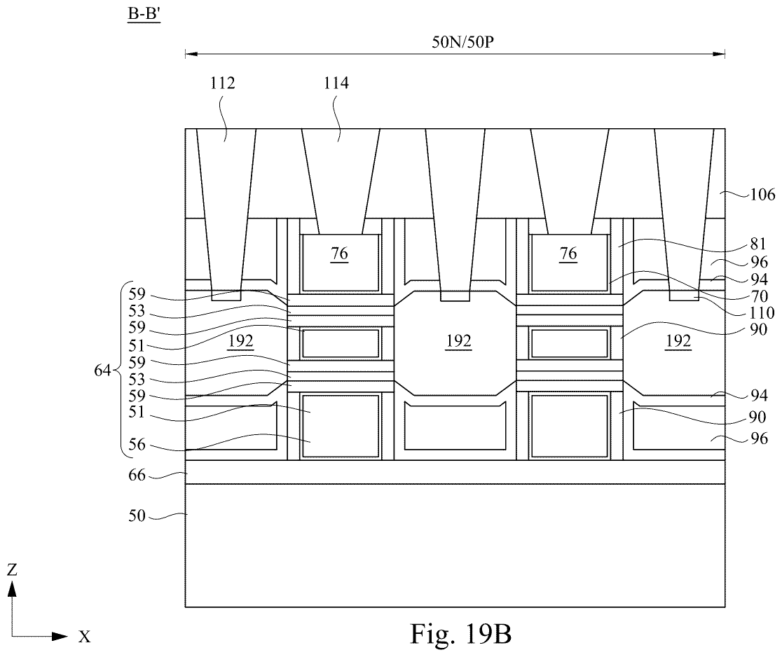

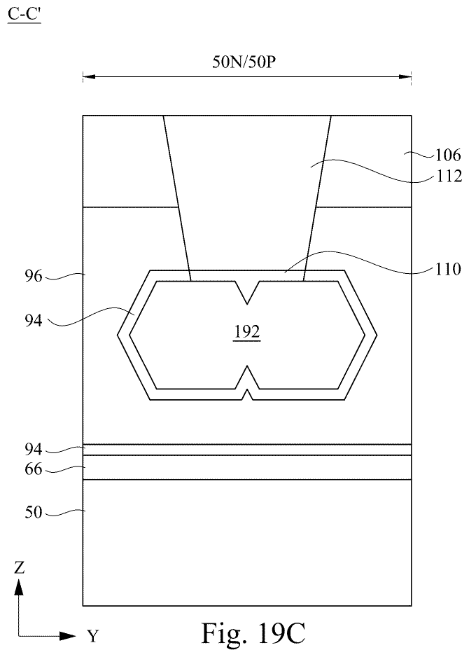

Operations for forming semiconductor structure after the structure shown in FIGS. 18A-18C and prior to the structure shown in FIGS. 19A-19C are substantially the same as the operations for forming the semiconductor structure shown in FIGS. 11A-14B, and reference may be made to the foregoing paragraphs for the related detailed descriptions and such descriptions are not provided again herein.

Reference is made to FIGS. 19A-19C. The dielectric layer 106, the ILD layer 96, the CESL 94, and the gate masks 104 are etched to form recesses 108 exposing surfaces of the source/drain regions 192 and/or the gate structure. The recesses 108 may be formed by etching using an anisotropic etching process, such as RIE, NBE, or the like. In some embodiments, the recesses 108 may be etched through the dielectric layer 106 and the ILD layer 96 using a first etching process; may be etched through the gate masks 104 using a second etching process; and may then be etched through the CESL 94 using a third etching process. A mask, such as a photoresist, may be formed and patterned over the dielectric layer 106 to mask portions of the dielectric layer 106 from the first etching process and the second etching process. In some embodiments, the etching process may over-etch, and therefore, the recesses 108 extend into the source/drain regions 192 and/or the gate structure, and a bottom of the recesses 108 may be level with (e.g., at a same level, or having a same distance from the substrate), or lower than (e.g., closer to the substrate) the source/drain regions 192 and/or the gate structure. Although FIG. 19B illustrate the recesses 108 as exposing the source/drain regions 192 and the gate structure in a same cross section, in various embodiments, the source/drain regions 192 and the gate structure may be exposed in different cross-sections, thereby reducing the risk of shorting subsequently formed contacts.

After the recesses 108 are formed, silicide regions 110 can be formed over the source/drain regions 192. In some embodiments, the silicide regions 110 can be formed by first depositing a metal (not shown) capable of reacting with the semiconductor materials of the underlying source/drain regions 192 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the source/drain regions 192, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 can include TiSi, and can have a thickness in a range between about 2 nm and about 10 nm. Subsequently, contacts 112 and 114 can be formed in the recesses 108. In some embodiments, the contacts 112 and 114 each can include a barrier layer and a conductive material, and is electrically coupled to the underlying conductive feature (e.g., gate electrode 102 and/or silicide region 110 in the illustrated embodiment).

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an incorporation of a high-k dielectric material (e.g., hafnium oxide (HfO₂)) etch stop layer in both the OD etch (see FIGS. 3A-3C) and sheet release etch processes (see FIGS. 12A-12C). Integration of high-k dielectric material below the nanostructure to act as an etch stop can improve process window and reduce pattern loading effects, which in turn improves pattern fidelity and uniformity.

In some embodiments, a method includes forming an etch stop layer over a substrate; forming a stack of alternating channel layers and sacrificial layers over the etch stop layer; etching the stack, until the etch stop layer is exposed, to form a fin-shaped structure; forming a source/drain features opposite sides of the stack; removing the sacrificial layers to release the channel layers; forming a gate structure to wrap around each of the channel layers. In some embodiments, the etch stop layer is made of a high-k dielectric material. In some embodiments, the etch stop layer comprises hafnium oxide. In some embodiments, the stack further comprises first and second protective layers sandwiching one of the channel layers. In some embodiments, the etch stop layer is made of a same material as the first and second protective layers. In some embodiments, the etch stop layer has a thickness that is thicker than the first and second protective layers. In some embodiments, the gate structure comprises a gate dielectric layer wrapping around the first and second protective layers and a gate electrode layer over the gate dielectric layer. In some embodiments, after etching the stack, a first portion of the etch stop layer overlapping the channel layers has a thicker thickness than a second portion of the etch stop layer non-overlapping the channel layers. In some embodiments, the channel layers are made of a two-dimensional material. In some embodiments, the sacrificial layers are made of a dielectric material.

In some embodiments, a method includes forming a metal oxide layer over a substrate; forming a first fin-shaped structure over the metal oxide layer, the first fin-shaped structure comprising a first stack of alternating first dielectric layers and first two-dimension material layers; forming source/drain terminals on either side of the first two-dimension material layers; performing an etching process, using a fluoride-containing precursor, to remove the first dielectric layers; forming a gate structure to wrap around each of the first two-dimension material layers. In some embodiments, the first dielectric layers are made of a material comprising silicon nitride, silicon oxide, or a combination thereof. In some embodiments, the fluoride-containing precursor comprises carbon tetrafluoride gas. In some embodiments, after performing the etching process, a first portion of the metal oxide layer overlapping the first two-dimension material layers has a thicker thickness than a second portion of the metal oxide layer non-overlapping the first two-dimension material layers. In some embodiments, the method further includes forming a second fin-shaped structure over the metal oxide layer, the second fin-shaped structure comprising a second stack of alternating second dielectric layers and second two-dimension material layers, wherein the second stack has a different lateral dimension than the first stack, and after performing the etching process, a first portion of the metal oxide layer overlapping first stack has a same thickness as a second portion of the metal oxide layer overlapping the second stack.

In some embodiments, a semiconductor structure includes a substrate, a two-dimension material channel layer, a gate structure, a plurality of source/drain patterns, and a high-k dielectric layer. The two-dimension material nanostructure is over the substrate. The gate structure wraps around the two-dimension material channel layer. The source/drain patterns are at opposite sides of the gate structure. The high-k dielectric layer is between the substrate and the gate structure, and between the substrate and the source/drain patterns. In some embodiments, the high-k dielectric layer is in contact with the source/drain patterns. In some embodiments, the gate structure comprises a gate dielectric layer wrapping around the two-dimension material channel layer and a gate electrode layer over the gate dielectric layer, and the high-k dielectric layer is in contact with the gate dielectric layer of the gate structure. In some embodiments, the high-k dielectric layer comprises hafnium oxide. In some embodiments, the high-k dielectric layer has a recessed portion non-overlapping with the two-dimension material channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an etch stop layer over a substrate;
forming a stack of alternating channel layers and sacrificial layers over the etch stop layer;
etching the stack, until the etch stop layer is exposed, to form a fin-shaped structure;
forming a source/drain features opposite sides of the stack;
removing the sacrificial layers to release the channel layers; and
forming a gate structure to wrap around each of the channel layers.

2. The method of claim 1, wherein the etch stop layer is made of a high-k dielectric material.

3. The method of claim 1, wherein the etch stop layer comprises hafnium oxide.

4. The method of claim 1, wherein the stack further comprises first and second protective layers sandwiching one of the channel layers.

5. The method of claim 4, wherein the etch stop layer is made of a same material as the first and second protective layers.

6. The method of claim 4, wherein the etch stop layer has a thickness that is thicker than the first and second protective layers.

7. The method of claim 4, wherein the gate structure comprises a gate dielectric layer wrapping around the first and second protective layers and a gate electrode layer over the gate dielectric layer.

8. The method of claim 1, wherein after etching the stack, a first portion of the etch stop layer overlapping the channel layers has a thicker thickness than a second portion of the etch stop layer non-overlapping the channel layers.

9. The method of claim 1, wherein the channel layers are made of a two-dimensional material.

10. The method of claim 1, wherein the sacrificial layers are made of a dielectric material.

11. A method, comprising:
forming a metal oxide layer over a substrate;
forming a first fin-shaped structure over the metal oxide layer, the first fin-shaped structure comprising a first stack of alternating first dielectric layers and first two-dimension material layers;
forming source/drain terminals on either side of the first two-dimension material layers;
performing an etching process, using a fluoride-containing precursor, to remove the first dielectric layers; and
forming a gate structure to wrap around each of the first two-dimension material layers.

12. The method of claim 11, wherein the first dielectric layers are made of a material comprising silicon nitride, silicon oxide, or a combination thereof.

13. The method of claim 11, wherein the fluoride-containing precursor comprises carbon tetrafluoride gas.

14. The method of claim 11, wherein after performing the etching process, a first portion of the metal oxide layer overlapping the first two-dimension material layers has a thicker thickness than a second portion of the metal oxide layer non-overlapping the first two-dimension material layers.

15. The method of claim 11, further comprising:
forming a second fin-shaped structure over the metal oxide layer, the second fin-shaped structure comprising a second stack of alternating second dielectric layers and second two-dimension material layers, wherein the second stack has a different lateral dimension than the first stack, and after performing the etching process, a first portion of the metal oxide layer overlapping first stack has a same thickness as a second portion of the metal oxide layer overlapping the second stack.

16. A semiconductor structure, comprising:
a two-dimension material channel layer over a substrate;
a gate structure wrapping around the two-dimension material channel layer;
a plurality of source/drain patterns at opposite sides of the gate structure; and
a high-k dielectric layer between the substrate and the gate structure, and between the substrate and the source/drain patterns.

17. The semiconductor structure of claim 16, wherein the high-k dielectric layer is in contact with the source/drain patterns.

18. The semiconductor structure of claim 16, wherein the gate structure comprises a gate dielectric layer wrapping around the two-dimension material channel layer and a gate electrode layer over the gate dielectric layer, and the high-k dielectric layer is in contact with the gate dielectric layer of the gate structure.

19. The semiconductor structure of claim 16, wherein the high-k dielectric layer comprises hafnium oxide.

20. The semiconductor structure of claim 16, wherein the high-k dielectric layer has a recessed portion non-overlapping with the two-dimension material channel layer.
